(19) United States
(12) Patent Application Publication
(10) Pub. No.: US 2008/0233283 A1
(43) Pub. Date: Sep. 25, 2008

(54) Apparatus for depositing protective layer and depositing method using the apparatus

(76) Inventors: Yong-Sup Choi, Suwon-si (KR); Jin-Pil Kim, Suwon-si (KR); Kang-Il Lee, Suwon-si (KR)

Correspondence Address: ROBERT E. BUSHNELL, 1522 K STREET NW, SUITE 300, WASHINGTON, DC, 20005-1202, US

(21) Appl. No.: 12/073,455

(22) Filed: Mar. 5, 2008

(30) Foreign Application Priority Data
Mar. 22, 2007 (KR) 10-2007-0028236

(51) Int. Cl. C23C 16/00

(52) U.S. Cl. 427/226; 118/719

(57) ABSTRACT

An apparatus and method for depositing a protective layer. The apparatus includes an anti-hydration module, wherein a substrate is loaded through a substrate input hole and mounted on a carrier; a load lock chamber, which is connected to the anti-hydration module and maintains a vacuum; a plurality of vacuum chambers; a depositing chamber, which is installed in one of the vacuum chambers; a target unit, which is installed in the depositing chamber and deposits a raw material of a protective layer on the substrate; a transferring unit which is continuously installed in the anti-hydration module, the load lock chamber, the vacuum chambers, and the depositing chamber, and transfers the substrate mounted on the carrier. Accordingly, since the carrier is not exposed to the atmosphere, moisture pressure inside the depositing chamber does not increase even if the apparatus is used for a long time.

### CLAIM OF PRIORITY

This application makes reference to, incorporates the same herein, and claims all benefits accruing under 35 U.S.C. §119 from an application earlier filed in the Korean Intellectual Property Office on Mar. 22, 2007 and there duly assigned Serial No. 10-2007-0028236.

### BACKGROUND OF THE INVENTION

1. Field of the Invention

The present invention relates to an apparatus for depositing a protective layer, and more particularly, to an apparatus for depositing a protective layer, which can prevent moisture inflow while depositing a protective layer on a substrate and can easily ventilate moisture, and an depositing method using the apparatus.

2. Description of the Related Art

Generally, a plasma display panel denotes a flat display device, wherein a plurality of discharge electrodes is formed between a plurality of substrates. Discharge gas is injected into a sealed discharge space between the substrates, and predetermined power is supplied to each discharge electrode. Accordingly, an image is realized by using light emitted by exciting a phosphoric material of a phosphor layer by using ultraviolet rays generated in the discharge space.

Processes of manufacturing a plasma display panel will now be described.

In the case of a first substrate, a first discharge electrode is formed on the first substrate, a first dielectric layer is printed so as to embed the first discharge electrode, and a protective layer is formed on the surface of the first dielectric layer. In the case of a second substrate, a second discharge electrode is formed on the second substrate, a second dielectric layer is printed so as to embed the second discharge electrode, barrier ribs are formed to divide discharge cells on the second dielectric layer, and red, green, and blue phosphor layers are coated on the inner surface of the barrier ribs.

Then, the first and second substrates are mutually aligned, and glass frit is coated on the facing inner boundaries of the first and second substrates. Accordingly, the first and second substrates are sealed together through a process of heat treatment at a predetermined temperature. In order to remove impurities, including moisture, which remains between the sealed first and second substrates, ventilation is performed in a vacuum. Next, a discharge gas, containing Xe—Ne as the main components, is injected between the first and second substrates, a predetermined power is supplied to the plasma display panel for aging discharge, and then an IC chip is installed. Thus, the plasma display panel is manufactured.

Here, the protective layer is formed of a material having a high secondary electron emission coefficient, such as MgO, and thus emits secondary electrons. Accordingly, the plasma display panel is induced to discharge gas at a low voltage.

With contemporary practice for depositing a protective layer, often some of the MgO raw material is also deposited on the carrier, which supports the substrate. Then, when an MgO thin film is exposed to moisture, the MgO thin film easily combines, physically or chemically, with the moisture. If the moisture, which is absorbed in the carrier, is discharged, the moisture changes an environment of the apparatus, and thus deteriorates the characteristics of the thin film. Also, as the carrier is exposed to the atmosphere, the characteristics of the thin film deteriorate due to moisture pressure.

In order to solve these problems, the carrier may be transferred only in a vacuum chamber, rather than being exposed to the atmosphere. When the carrier is transferred in a vacuum, these problems caused by moisture absorption by the raw MgO adhering to the carrier can be prevented, however the necessity of installing and removing the substrate while the carrier in a vacuum, is complicated.

In more recent efforts, a large-sized substrate is mounted on the carrier, and a deposition side of the substrate is covered by a mask in order to manufacture panels of a desired size. Rollers are used to transfer the substrate to a carrier return chamber. The rollers contact boundaries of the substrate and a part covered by the mask; the distances between the rollers and locations of the rollers are frequently changed, and thus the locations of the rollers should be rearranged in order to change the type of panel. In order to rearrange the distances of the rollers, the vacuum is lost and additional time is required in order to set conditions for depositing a protective layer. Accordingly, productivity of panels is substantially limited.

It is therefore, an object of the present invention to provide an improved method and an improved process for depositing a protective layer on a substrate.

It is another object to provide a method and apparatus for depositing onto a substrate, a protective layer that is able to easily ventilate moisture while prevent moisture inflow.

### SUMMARY OF THE INVENTION

The present invention provides an apparatus for depositing a protective layer, which can prevent a carrier from being exposed to external moisture by forming a chamber in a substrate loading part of the carrier, where a substrate is mounted, so as to form a nitrogenous or clean dry atmosphere and maintaining positive pressure, and a depositing method using the apparatus.

According to an aspect of the present invention, there is provided an apparatus for depositing a protective layer, the apparatus including: an anti-hydration module, wherein a substrate is loaded through a substrate input hole and which provides a space for mounting the substrate on a carrier; a load lock chamber, which is connected to the anti-hydration module and maintains a vacuum; a plurality of vacuum chambers, which are connected to the load lock chamber and wherein the substrate mounted on the carrier is transferred; a depositing chamber, which is installed in one of the vacuum chambers; a target unit, which is installed in the depositing chamber and deposits a raw material of a protective layer on the substrate; a transferring unit which is continuously installed in the anti-hydration module, the load lock chamber, the vacuum chambers, and the depositing chamber, and transfers the substrate mounted on the carrier; and gate valves, which are installed in boundaries of the anti-hydration module, the load lock chamber, the vacuum chambers, and the deposition chamber, and selectively open or close each of the anti-hydration module, the load lock chamber, the vacuum chambers, and the deposition chamber.

The anti-hydration module may have an inert atmosphere or clean dry air.

The apparatus may further include a slit, which is formed between the substrate input hole and the anti-hydration module, is selectively opened or closed by a door, and provides a passage in which the substrate is loaded.

The transferring unit may include carrier rollers which transfer the carrier, and substrate rollers which transfer the substrate.

The carrier rollers may be continuously located in the anti-hydration module, the load lock chamber, the vacuum chambers, and the depositing chamber.

The substrate rollers may be installed inside the anti-hydration module.

According to another aspect of the present invention, there is provided a method of depositing a protective layer, the method including: loading a substrate through a substrate input hole to an anti-hydration module; mounting the loaded substrate on a carrier by using a top and bottom transferring unit; transferring the substrate, mounted on the carrier, to a load lock chamber; passing the substrate, mounted on the carrier, through a plurality of vacuum chambers; depositing a protective layer on the substrate by using a target unit of an depositing chamber between the vacuum chambers; and picking up the substrate, in which the protective layer is deposited, after the substrate passes through the vacuum chambers, the load lock chamber, and the anti-hydration module.

The substrate may be loaded into the anti-hydration module through a slit, which is installed between the substrate input hole and the anti-hydration module.

The mounting of the substrate on the carrier may include: raising the carrier, which is supported by carrier rollers, towards the substrate; seating an upper surface of the carrier on a bottom boundary surface of the substrate; separating substrate rollers, which support the substrate, from the substrate by lowering the substrate rollers; and transferring the carrier, in which the substrate is mounted, by using the carrier rollers.

The mounting of the substrate on the carrier could be done directly by robot through a slit.

The method may further include discharging moisture, which is deposited from the substrate mounted on the carrier and passing through an upper part of the some chambers and the depositing chamber, by installing a top and bottom separator in the some chambers and the depositing chamber.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a diagram illustrating a contemporary apparatus for depositing a protective layer;

FIG. 2 is a diagram illustrating another contemporary apparatus for depositing a protective layer;

FIG. 3 is a plan view illustrating a contemporary substrate mounted on a carrier;

FIG. 4 is a diagram illustrating another contemporary apparatus for depositing a protective layer;

FIG. 5 is a diagram illustrating an apparatus for depositing a protective layer according to an embodiment of the present invention;

FIGS. 6A, 6B, and 6C are enlarged diagrams illustrating A of FIG. 5 according to embodiments of the present invention;

FIG. 7A is a cross-sectional view illustrating a carrier of FIG. 5 before a substrate is mounted; and

FIG. 7B is a cross-sectional view illustrating a carrier of FIG. 7A after a substrate is mounted.

### DETAILED DESCRIPTION OF THE INVENTION

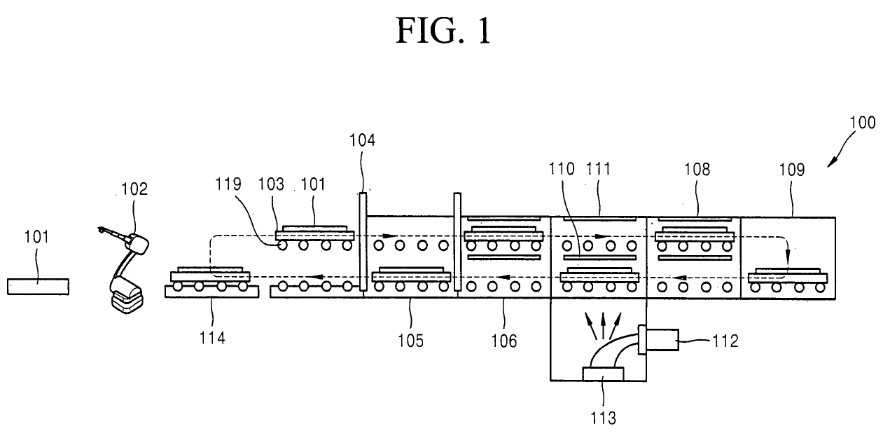

Turning now to the drawings, FIG. 1 is a diagram illustrating a contemporary apparatus 100 for depositing a protective layer.

Referring to FIG. 1, a substrate 101 is mounted on a carrier 103 by a robot 102.

The substrate 101, mounted on the carrier 103, is loaded into a load lock chamber 105 as a first gate valve 104 opens. At this time, the carrier 103 is transferred as rollers 119 roll.

The substrate 101, which is mounted on the carrier 103 loaded into the load lock chamber 105, is transferred to a buffer unit-1 chamber 106. While the substrate 101 is transferred from the buffer unit-1 chamber 106, to an upper part of an deposition chamber 111, to a buffer unit-2 chamber 108, and then to a return chamber 109, the substrate 101 is heated to a processing temperature by a heater 110.

An MgO raw material is deposited on the substrate 101, which is mounted on the carrier 103, as the substrate 101 is transferred from the bottom part of the return chamber 109, to the bottom part of the buffer unit-2 chamber 108, and then to the bottom part of the deposition chamber 111. MgO particles deposited on the substrate 101 are evaporated by melting a MgO raw material on a hearth 113 by using a plasma or electron beam source 112.

Then, the substrate 101 is transferred from the bottom part of the buffer unit-1 chamber 106, the load lock chamber 105, and to a substrate pickup and loading platform 114. Accordingly, the substrate 101 is picked up by the robot 102.

However, while depositing the MgO raw material on the substrate 101, some of the MgO raw material is also deposited on the carrier 103, which supports the substrate 101. When an MgO thin film is exposed to moisture, the MgO thin film easily combines, physically or chemically, with the moisture. If the moisture, which is absorbed in the carrier 103, is discharged in the apparatus 100, the moisture changes an environment of the apparatus 100, and thus deteriorates the characteristics of the MgO thin film. Also, as the carrier 103 is exposed to the atmosphere, the characteristics of the MgO thin film deteriorate due to moisture pressure.

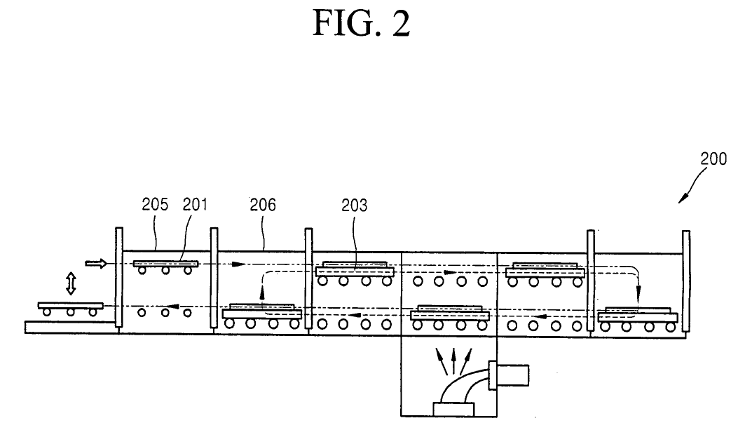

In order to solve the above problem, an apparatus 200 for depositing a protective layer, which uses a transfer only substrate system (TOSS) of Anelva Corp. in Japan, as illustrated in FIG. 2 is used. According to the apparatus 200, a carrier 203 is transferred only in a vacuum chamber, and is not exposed to the atmosphere.

Referring to FIG. 2, a substrate 201, which is loaded into a load lock chamber 205, is mounted on the carrier 203 in a carrier return chamber 206. Before a new substrate 201 is mounted on the carrier 203, a pre-mounted substrate 201 is transferred from the bottom part of the carrier return chamber 206 to the load lock chamber 205. Then, the carrier 203, without any substrate, is transferred to an upper part of the carrier return chamber 206 so that the new substrate 201 can be mounted.

According to the TOSS, since the carrier 203 can be transferred in a vacuum, problems of moisture absorption by MgO adhering to the carrier 203 can be prevented. However, since the substrate 201 and the carrier 203 should be attached and detached in a vacuum, substrate transference is complicated.

Recently, a multi separated panel method has been applied to a substrate for a panel, wherein a large substrate is divided into panels of a desired size.

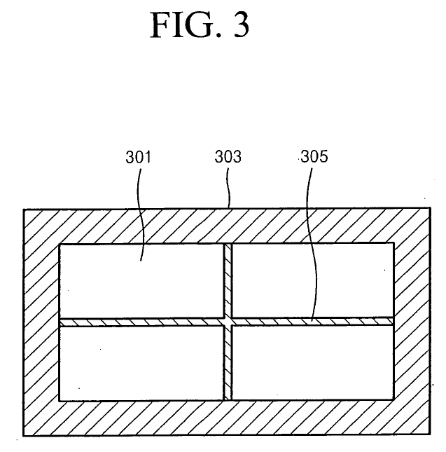

FIG. 3 is a plan view illustrating a contemporary substrate 301 for a multi separated panel, a carrier 303, and a mask 305.

Referring to FIG. 3, the large-sized substrate 301 is mounted on the carrier 303, and a deposition side of the substrate 301 is covered by the mask 305 in order to manufacture panels of a desired size. In an apparatus for depositing a protective layer, which uses the TOSS in a similar manner as used by the apparatus 200 of FIG. 2, rollers are used to transfer the substrate 301 to a carrier return chamber 206.

Here, parts that the substrate 301 and the rollers contact are boundaries of the substrate 301 and a part covered by the mask 305. In order to manufacture panels of various sizes by using the apparatus, distances between the rollers and locations of the rollers should change. If the substrate 301 is transferred after being mounted on the carrier 303, a roller distance problem does not occur, but in the case of the TOSS, only the substrate 301 is transferred to the carrier return chamber 206 of FIG. 2, and thus the locations of the rollers should be rearranged in order to change the type of panel. In order to rearrange the distances of the rollers, a vacuum should be removed and a lot of time is required in order to set conditions for depositing a protective layer. Accordingly, productivity of panels may deteriorate.

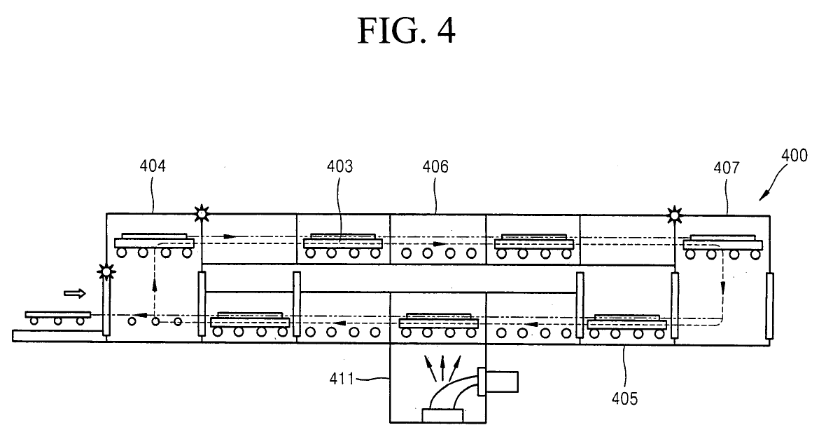

In the case of an apparatus 400 for depositing a protective layer, which uses a clean dry air (CDA) method of UIVA in Japan, illustrated in FIG. 4, attaching and detaching a substrate 401 and a carrier 403 are performed in a substrate pickup and loading platform 404, which is managed with dry air, instead of a vacuum as with the TOSS. The newly mounted substrate 401 is transferred to a carrier vacuum loading chamber 407 through a CDA passage 406, and then is loaded into a depositing chamber 411 through a load lock chamber 405.

The CDA method is advantageous in terms of changing the type of panel compared to the TOSS, but cannot completely prevent the carrier 403, wherein MgO is adhered, from contacting the atmosphere. Accordingly, the depositing chamber 411 cannot manage impurities better than an depositing chamber using the TOSS. Also, it is costly to keep the air of the CDA passage 405 dry.

Hereinafter, the present invention will be described more fully with reference to the accompanying drawings, in which exemplary embodiments of the invention are shown.

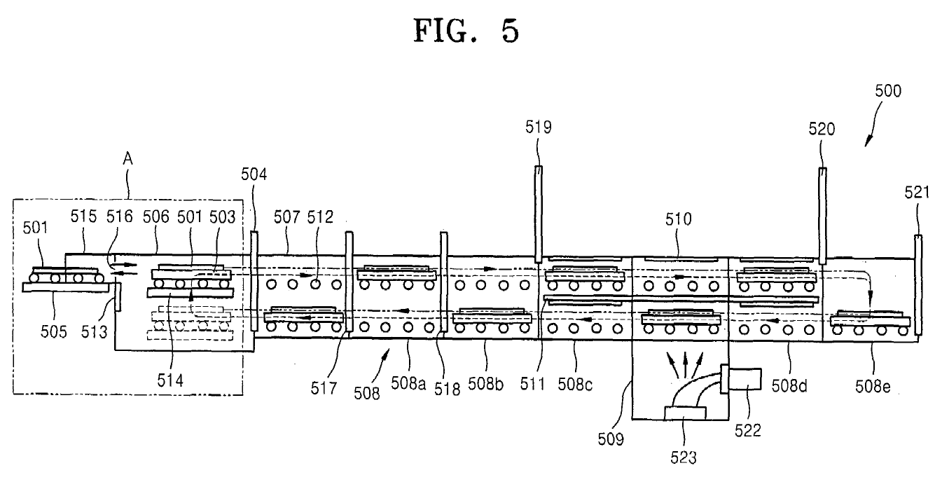

FIG. 5 is a diagram illustrating an apparatus 500 for depositing a protective layer according to an embodiment of the present invention.

Referring to FIG. 5, the apparatus 500 includes an anti-hydration module 506, a load lock chamber 507 connected to the anti-hydration module 506, a plurality of vacuum chambers 508 connected to the load lock chamber 507, and an depositing chamber 509 installed inside the vacuum chambers 508.

A substrate input hole 515, to which a substrate 501 on a substrate input unit 505 is transferred, is formed in a separate chamber in front of the anti-hydration module 506. The substrate input hole 515 is connected to the anti-hydration module 506 through a slit 516. The substrate input hole 515 can minimize the amount of inert gas, clean dry air or nitrogen consumed in the anti-hydration module 506 since the substrate input hole 515 is combined to an upper part of the anti-hydration module 506, which maintains an inert atmosphere.

The slit 516 is formed in the smallest size possible that the substrate 501 on the substrate input unit 505 can be loaded into, and maintains positive pressure inside the anti-hydration module 506. A door 513 is installed in the slit 516 so that the slit 516 can be selectively opened or closed. The door 513 opens when the substrate 501 is loaded and closes at other times. Accordingly, loss of inert gas clean dry air, or nitrogen inside the anti-hydration module 506 can be prevented.

Inert gas, such as nitrogen, is injected into the anti-hydration module 506. Accordingly, the internal anti-hydration module 506 maintains an atmosphere of inert gas, and thus moisture pressure does not exist.

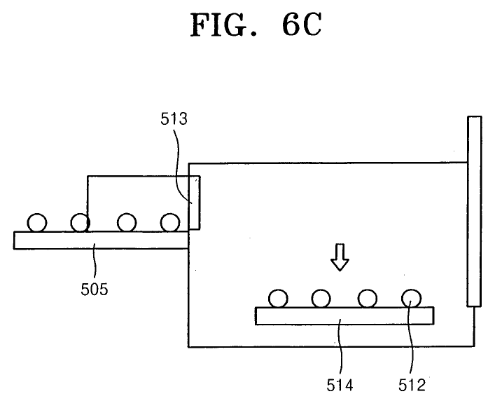

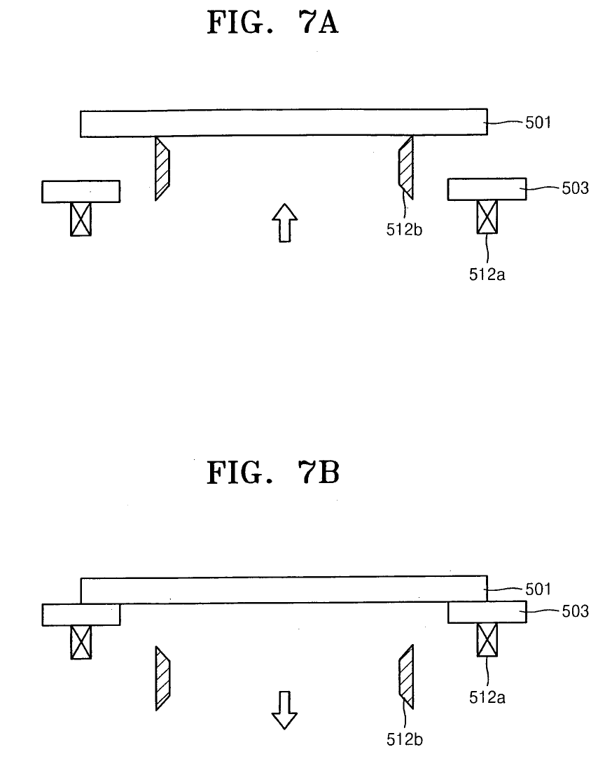

Rollers 512, which transfer the substrate 501 mounted on a carrier 503, are installed inside the anti-hydration module 506, the load lock chamber 507, the plurality of vacuum chambers 508, and the depositing chamber 509. The rollers 512 include carrier rollers 512a and substrate rollers 512b as illustrated in FIG. 7A. The carrier rollers 512a roll in an endless track inside the anti-hydration module 506, the load lock chamber 507, the vacuum chambers 508, and the depositing chamber 509. The substrate rollers 512b are used to mount the substrate 501, which is loaded from the substrate input hole 515, on the carrier 503 in the anti-hydration module 506.

The anti-hydration module 506 includes a top and bottom transferring unit 514, which lifts and lowers the carrier rollers 512a and the substrate rollers 512b. A structure of the top and bottom transferring unit 514 is not limited as long as the structure can lift and lower the carrier rollers 512a and the substrate rollers 512b by using elevating means, such as a hydraulic cylinder. In the anti-hydration module 506, the carrier 503 can be removed from the substrate 501 by using the carrier rollers 512a, the substrate rollers 512b and the top and bottom transferring unit 514.

A first gate valve 504 is installed between the anti-hydration module 506 and the load lock chamber 507. A second gate valve 517 is installed between the load lock chamber 507 and the vacuum chamber 508. Accordingly, after the substrate 501, mounted on the carrier 503 is loaded into the load lock chamber 507, the first and second gate valves 504 and 517 occlude the load lock chamber 507 so that the pressure inside the load lock chamber 507 is similar to the pressure inside the vacuum chamber 508.

The vacuum chamber 508 is divided into a first chamber 508a, a second chamber 508b, a third chamber 508c, a fourth chamber 508d, and a fifth chamber 508e by installing a plurality of gate valves, which are a third gate valve 518, a fourth gate valve 519, a fifth gate valve 520, and a sixth gate value 521. The vacuum chamber 508 can gradually maintain the vacuum by being divided into the plurality of chambers 508a through 508e. When there is disorder in one chamber, the chamber can be easily repaired by occluding the chamber by using corresponding gate valves.

A depositing chamber 509 is installed between the third chamber 508c and the fourth chamber 508d. A plurality of heaters 510 are installed in the third chamber 508c, the depositing chamber 509, and the fourth chamber 508d. The substrate 501 mounted on the carrier 503 inserted through the anti-hydration module 506 is heated by the heaters 510.

The contemporary apparatuses 100, 200, and 400 of FIGS. 1, 2, and 4 increase the moisture pressure inside a depositing chamber by emitting moisture adsorbed in a carrier and a substrate during heating. The moisture pressure increases since the emitted moisture is emitted through a vacuum pump below the depositing chamber.

In the current embodiment, since a top and bottom separator 511, which separates the depositing chamber 509, is installed, a vacuum is separately pumped to the top and bottom transferring unit 514. In this case, the moisture emitted from the substrate 501 or the carrier 503 is not moved to the bottom of the depositing chamber 509 but is ventilated, and thus the moisture pressure inside the depositing chamber 509 is not increased. The heaters 510 are each installed in the upper and lower parts divided by the top and bottom separator 511, and the heaters 510 can be used instead of the top and bottom separator 511.

A target unit, such as a plasma or electron beam source 522, is installed in the depositing chamber 509 in order to form a protective layer on the substrate 501 and a hearth 523 is installed near the plasma or electron beam source 522. Accordingly, the raw material of the protective layer, such as MgO, which is deposited on the substrate 501, can be melted on the hearth 523 and deposited by the plasma or electron beam source 522.

Operations of the apparatus 500 of the current embodiment will now be described with reference to FIGS. 5, 6A through 6C, 7A, and 7B.

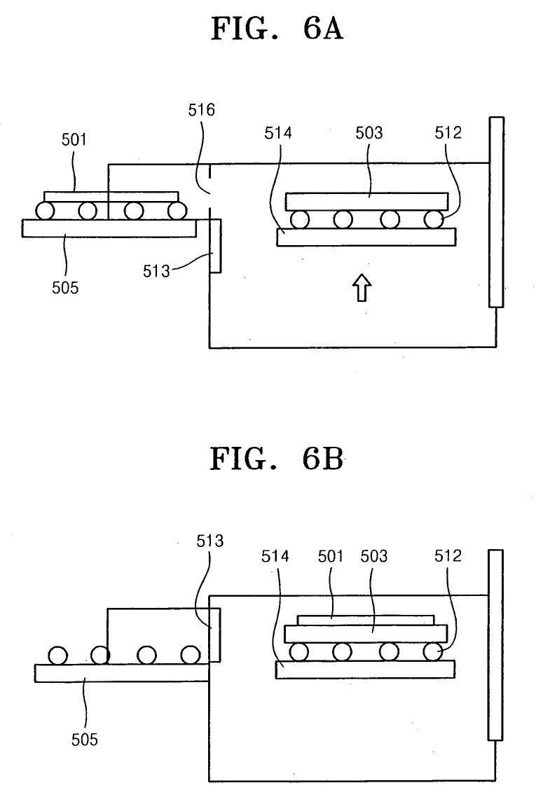

First, as illustrated in FIG. 6A, the substrate 501 is loaded into the substrate input hole 515 through the slit 516. Here, since the carrier 503 is not exported to the substrate input hole 515, only the substrate 501 is transferred. The carrier 503 on the rollers 512 rises by the top and bottom transferring unit 514 in the anti-hydration module 506.

Next, as illustrated in FIG. 6B, the substrate 501, which is loaded through the substrate input hole 515, is mounted on the carrier 503. After the substrate 501 is loaded into the anti-hydration module 506, the slit 516 is sealed by the door 513, and thus the internal anti-hydration module 506 maintains the positive pressure. When the substrate 501, mounted on the carrier 503 enters the load lock chamber 507, the top and bottom transferring unit 514 descends as illustrated in FIG. 6C.

FIG. 7A illustrates a process of mounting the substrate 501 on the carrier 503. When the substrate 501, while being supported on the substrate rollers 512b, is loaded into the anti-hydration module 506 through the slit 516, the carrier rollers 512a, which support the carrier 503, ascend by the top and bottom transferring unit 514.

Here, the carrier 503 is in a square frame shape and the substrate 501 is formed of a board-shaped glass. Accordingly the bottom surface of the substrate 501 is supported by the substrate rollers 512b and the bottom surface of the carrier 503 is supported by the carrier rollers 512a, and thus the substrate 501 and the carrier 503 can separately operate.

Then, as illustrated in FIG. 7B, the bottom surface of the substrate 501, transferred by the substrate rollers 512b, is seated on the top surface of the carrier 503, which is supported by the ascended carrier rollers 512a. When the substrate 501 is seated on the carrier 503, the substrate rollers 512b are descended to the bottom part of the anti-hydration module 506 by the top and bottom transferring unit 514.

Accordingly, the substrate 501 is mounted on the carrier 503, and the carrier 503 is transferred to the load lock chamber 507 by the carrier rollers 512a. Also, the substrate rollers 512b move up and down only inside the anti-hydration module 506.

Then, the first gate valve 504 is opened, and the substrate 501 mounted on the carrier 503 is transferred to the load lock chamber 507 as the carrier rollers 512a rotate. Here, the pressure inside the load lock chamber 507 is adjusted to be equal to the pressure inside the first vacuum chamber 508a by using a vacuum pump.

Next, the second gate valve 517 is opened, and the substrate 501 mounted on the carrier 503 passes the first vacuum chamber 508a, the second vacuum chamber 508b, the upper parts of the third vacuum chamber 508c, the depositing chamber 509, and the fourth vacuum chamber 508d, which are divided by the top and bottom separator 511.

Here, the heaters 510 are installed in the upper parts of the third vacuum chamber 508c, the depositing chamber 509, and the fourth vacuum chamber 508d, and thus the heater 501, mounted on the carrier 503, emits moisture by being heated by the heaters 510. The heating temperature of the heaters 510 is approximately between 100 to 400° C., and preferably approximately 250° C. The emitted moisture is quickly exhausted from the upper parts of the third vacuum chamber 508c, the depositing chamber 509, and the fourth vacuum chamber 508d by using a separate vacuum pump.

The substrate 501, mounted on the carrier 503, passes through and is returned in the fifth chamber 508e, and then passes through the bottom parts of the fourth chamber 508d and the depositing chamber 509.

When the substrate 501, mounted on the carrier 503, is transferred to the bottom part of the depositing chamber 509, the raw material of the protective layer is deposited on the substrate 501. Particles of the protective layer, such as MgO, deposited on the substrate 501 are deposited by melting the raw material on the hearth 523 by using the plasma or electron beam source 522.

Then, the substrate 501, mounted on the carrier 503, is transferred to the bottom part of the third chamber 508c, the second chamber 508b, and the first chamber 508a. When the second gate valve 517 opens, the substrate 501, mounted on the carrier 503, is then transferred to the load lock chamber 507. After a predetermined cooling time, the substrate 501, mounted on the carrier 503, is transferred to the anti-hydration module 506 as the first gate valve 504 opens.

The substrate 501, mounted on the carrier 503, is transferred to the upper part of the anti-hydration module 506 by the top and bottom transferring unit 514 according to the interaction of the carrier rollers 512a and the substrate rollers 512b. Then, the door 513 opens the slit 506, and the substrate 501 is picked up and loaded to the substrate input hole 515 by the substrate rollers 512b.

As described above, the following effects can be obtained by using the method and apparatus of the present invention.

First, since a carrier is not exposed to the atmosphere, the moisture pressure inside an depositing chamber does not increase even if the carrier is used for a long time. Accordingly, a uniform quality of a deposited protective layer can be achieved.

Second, since the moisture pressure inside the depositing chamber does not increase after a predetermined time, the carrier can be maintained for a long time, and thus productivity of the carrier can be improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An apparatus for depositing a protective layer, the apparatus comprising:
an anti-hydration module, wherein a substrate is loaded through a substrate input hole and which provides a space for mounting the substrate on a carrier;
a load lock chamber, which is connected to the anti-hydration module and maintains a vacuum;
a plurality of vacuum chambers, which are connected to the load lock chamber and wherein the substrate mounted on the carrier is transferred;
a depositing chamber, which is installed in one of the vacuum chambers;
a target unit, which is installed in the depositing chamber and deposits a raw material of a protective layer on the substrate;
a transferring unit which is continuously installed in the anti-hydration module, the load lock chamber, the vacuum chambers, and the depositing chamber, and transfers the substrate mounted on the carrier; and
gate valves, which are installed in boundaries of the anti-hydration module, the load lock chamber, the vacuum chambers, and the deposition chamber, and selectively open or close each of the anti-hydration module, the load lock chamber, the vacuum chambers, and the deposition chamber.

2. The apparatus of claim 1, wherein the anti-hydration module has an inert atmosphere.

3. The apparatus of claim 1, further comprising a slit, which is formed between the substrate input hole and the anti-hydration module, is selectively opened or closed by a door, and provides a passage in which the substrate is loaded.

4. The apparatus of claim 1, wherein the vacuum chamber is divided into a plurality of chambers so as to maintain a vacuum in a multi-stage.

5. The apparatus of claim 1, wherein some vacuum chambers and the depositing chamber are divided into upper and bottom parts by a top and bottom separator.

6. The apparatus of claim 5, wherein heaters, which heat up the substrate, are installed in some vacuum chambers and the depositing chamber.

7. The apparatus of claim 1, wherein the target unit comprises a plasma or electron beam source and a hearth, wherein a raw material of the protective layer is mounted.

8. The apparatus of claim 1, wherein the transferring unit comprises carrier rollers which transfer the carrier, and substrate rollers which transfer the substrate.

9. The apparatus of claim 8, wherein the carrier rollers are continuously located in the anti-hydration module, the load lock chamber, the vacuum chambers, and the depositing chamber.

10. The apparatus of claim 8, wherein the substrate rollers are installed inside the anti-hydration module.

11. The apparatus of claim 10, wherein the anti-hydration module comprises a top and bottom transferring unit, which lifts and lowers the carrier rollers and the substrate rollers.

12. A method of depositing a protective layer, the method comprising:
loading a substrate through a substrate input hole to an anti-hydration module;
mounting the loaded substrate on a carrier by using a top and bottom transferring unit;
transferring the substrate, mounted on the carrier, to a load lock chamber;
passing the substrate, mounted on the carrier, through a plurality of vacuum chambers;
depositing a protective layer on the substrate by using a target unit of an depositing chamber between the vacuum chambers; and
picking up the substrate, in which the protective layer is deposited, after the substrate passes through the vacuum chambers, the load lock chamber, and the anti-hydration module.

13. The method of claim 12, wherein the substrate is loaded into the anti-hydration module through a slit, which is installed between the substrate input hole and the anti-hydration module.

14. The method of claim 12, wherein the mounting of the substrate on the carrier comprises:
raising the carrier, which is supported by carrier rollers, towards the substrate;
seating an upper surface of the carrier on a bottom boundary surface of the substrate;
separating substrate rollers, which support the substrate, from the substrate by lowering the substrate rollers; and
transferring the carrier, in which the substrate is mounted, by using the carrier rollers.

15. The method of claim 12, wherein the internal anti-hydration module maintains an inert atmosphere.

16. The method of claim 12, further comprising adjusting pressure of the load lock chamber correspondingly to pressure of an adjacently connected vacuum chamber by closing a gate valve after the substrate, mounted on the carrier, is transferred.

17. The method of claim 12, further comprising depositing moisture of the substrate, mounted on the carrier, while the substrate passes through some vacuum chambers and the depositing chamber, installed between the vacuum chambers, by heating heaters installed inside the some vacuum chambers and the depositing chamber.

18. The method of claim 12, further comprising depositing moisture of the substrate, mounted on the carrier, while the substrate passes through some vacuum chambers and the depositing chamber, installed between the vacuum chambers, by heating heaters installed inside the some vacuum chambers and the depositing chamber.

19. The method of claim 18, further comprising discharging moisture, which is deposited from the substrate mounted on the carrier and passing through an upper part of the some chambers and the depositing chamber, by installing a top and bottom separator in the some chambers and the depositing chamber.

20. The method of claim 12, wherein moisture is removed using a vacuum from said substrate and said carrier and is prevented from accumulating in said depositing chamber.
